(19) United States
(12) Patent Application Publication
(10) Pub. No.: US 2020/0075314 A1
(43) Pub. Date: Mar. 5, 2020

(54) DOPED BUFFER LAYER FOR GROUP III-V DEVICES ON SILICON

(71) Applicant: Taiwan Semiconductor Manufacturing Co., Ltd., Hsin-Chu (TW)

(72) Inventors: Chi-Ming Chen, Zhubei City (TW); Chung-Yi Yu, Hsin-Chu (TW); Kuei-Ming Chen, New Taipei City (TW)

(21) Appl. No.: 16/395,673

(22) Filed: Apr. 26, 2019

Related U.S. Application Data
(60) Provisional application No. 62/724,303, filed on Aug. 29, 2018.

(51) Int. Cl. H01L 21/02; H01L 29/20; H01L 29/205; H01L 29/778; H01L 23/00; H01L 29/66

(52) U.S. Cl. CPC H01L 21/0251; H01L 29/2003; H01L 29/205; H01L 29/7787; H01L 29/66462; H01L 21/02381; H01L 21/02458; H01L 21/0254; H01L 23/562

(57) ABSTRACT

Various embodiments of the present application are directed towards a group III-V device including a seed buffer layer that is doped and that is directly on a silicon substrate. In some embodiments, the group III-V device includes the silicon substrate, the seed buffer layer, a heterojunction structure, a pair of source/drain electrodes, and a gate electrode. The seed buffer layer overlies and directly contacts the silicon substrate. Further, the seed buffer layer includes a group III nitride (e.g., AlN) that is doped with p-type dopants. The heterojunction structure overlies the seed buffer layer. The source/drain electrodes overlie the heterojunction structure. The gate electrode overlies the heterojunction structure, laterally between the source/drain electrodes. The p-type dopants prevent the formation of a two-dimensional hole gas (2DHG) in the silicon substrate, along an interface at which the silicon substrate and the seed buffer layer directly contact.

### REFERENCE TO RELATED APPLICATION

This application claims the benefit of U.S. Provisional Application No. 62/724,303, filed on Aug. 29, 2018, the contents of which are hereby incorporated by reference in their entirety.

### BACKGROUND

Semiconductor devices based on silicon have been the standard for the past few decades. However, semiconductor devices based on alternative materials are receiving increasing attention for advantages over silicon-based semiconductor devices. For example, semiconductor devices based on group III-V semiconductor materials have been receiving increased attention due to high electron mobility and wide band gaps compared to silicon-based semiconductor devices. Such high electron mobility and wide band gaps allow improved performance and high temperature applications.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of a group III-V device comprising a seed buffer layer that is doped.

FIGS. 2A-2D illustrate cross-sectional views of various alternative embodiments of the group III-V device of FIG. 1 having different configurations for the seed buffer layer.

FIGS. 3A-3C illustrate cross-sectional views of various alternative embodiments of the group III-V device of FIG. 1 having different gate electrode configurations.

FIGS. 4A-4B illustrate various views of some alternative embodiments of the group III-V device of FIG. 1 in which the group III-V device further comprises a super lattice layer.

FIG. 5 illustrates some alternative embodiments of the group III-V device of FIG. 1 having a different barrier layer configuration.

FIGS. 6-11 illustrate a series of cross-sectional views of some embodiments of a method for forming a group III-V device comprising a seed buffer layer that is doped.

FIG. 12 illustrates a flowchart of some embodiments of the method of FIGS. 6-11.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Group III nitride devices are often formed on silicon substrates. Among other things, silicon substrates are cheap and readily available in a wide variety of sizes. A group III nitride device formed on a silicon substrate may comprise a buffer layer overlying the silicon substrate, a channel layer overlying the buffer layer, and a barrier layer overlying the channel layer. The silicon substrate has a crystalline orientation of (111) and contacts the buffer layer. The buffer layer is undoped aluminum nitride (AlN) and serves as a seed for epitaxially forming an overlying layer (e.g., another buffer layer). The channel layer and the barrier layer contact to define a heterojunction and may respectively be, for example, undoped gallium nitride (GaN) and aluminum gallium nitride (AlGaN).

A challenge with the group III nitride device is that the buffer layer induces band bending in the silicon substrate, along an interface at which the buffer layer and the silicon substrate contact. The band banding results in the formation of a two-dimensional hole gas (2DHG) in the silicon substrate. The 2DHG has a low resistivity compared to a remainder of the silicon substrate, such that the average resistivity of the silicon substrate is reduced (e.g., from about 1800 ohms to about 900 ohms). This leads to substrate losses and reduces the power added efficiency (PAE) of the group III nitride device (e.g., by about 10% or more).

Various embodiments of the present application are directed towards a group III-V device comprising a seed buffer layer that is doped and that is directly on a silicon substrate. In some embodiments, the group III-V device comprises the silicon substrate, the seed buffer layer, a heterojunction structure, a pair of source/drain electrodes, and a gate electrode. The seed buffer layer overlies and directly contacts the silicon substrate. Further, the seed buffer layer is or comprises a group III nitride (e.g., AlN) that is doped with p-type dopants (e.g., magnesium, iron, carbon, or zinc). The heterojunction structure overlies the seed buffer layer. The source/drain electrodes are on the heterojunction structure. The gate electrode is on the heterojunction structure, laterally between the source/drain electrodes.

The seed buffer layer induces band bending in the silicon substrate. In at least some embodiments, the band bending would induce formation of a 2DHG in the silicon substrate if the seed buffer layer was undoped or intrinsic. However, because the seed buffer layer is doped with p-type dopants, the holes in the seed buffer layer are the majority carrier and repel holes that would form the 2DHG. By repelling holes that would form the 2DHG, the 2DHG is prevented from forming. This prevents the 2DHG from negatively impacting (e.g., decreasing) a resistance of the substrate, reduces substrate losses, and enhances the PAE of the group III-V device.

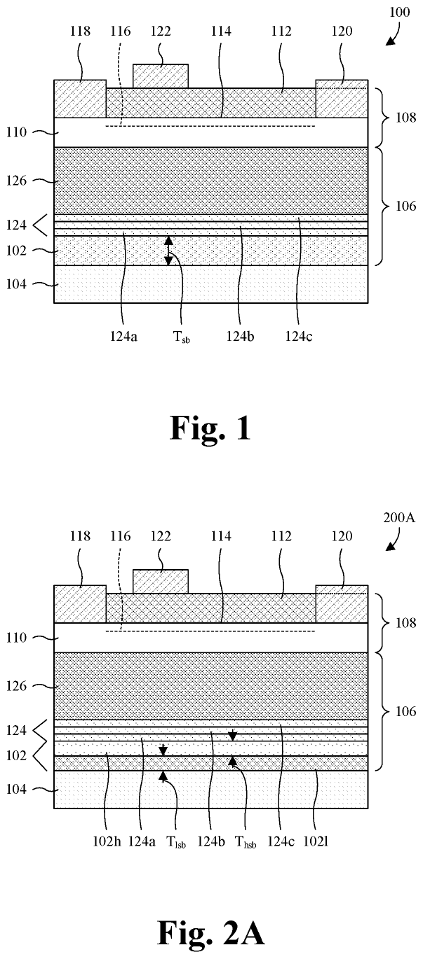

With reference to FIG. 1, a cross-sectional view 100 of some embodiments of a group III-V device comprising a seed buffer layer 102 that is doped is provided. The group III-V device may be, for example, a group III nitride device and/or may, for example, be a depletion mode high electron mobility transistor (D-HEMT). The substrate 104 may, for example, be or comprise monocrystalline silicon, silicon carbide, or some other semiconductor material, and/or may, for example, have a crystalline orientation of (111) or some other crystalline orientation. Further, the substrate 104 may, for example, be a bulk semiconductor substrate and/or may, for example, be a semiconductor wafer (e.g., a 300 or 450 nanometer semiconductor wafer). In some embodiments, the substrate 104 has a high resistance to reduce substrate losses. The high resistance may, for example, be greater than about 1, 1.8, or 3 kilo-ohms/centimeter (1M/cm) and/or between about 1-1.8 kΩ/cm, or about 1.8-3 kΩ/cm. Further, in some embodiments, the substrate 104 is doped with p-type dopants to achieve the high resistance.

A buffer structure 106 overlies the substrate 104 and comprises the seed buffer layer 102. The buffer structure 106 may, for example, serve to compensate for differences in lattice constants, crystalline structures, and thermal expansion coefficients between the substrate 104 and a heterojunction structure 108 overlying the buffer structure 106. The seed buffer layer 102 overlies and directly contacts the substrate 104 and serves as a seed or nucleation layer for growing a group III-V layer on the substrate 104.

The seed buffer layer 102 is or comprises AlN, some other group III nitride, or some other group III-V material. In some embodiments, the seed buffer layer 102 is or comprises low temperature AlN. The low temperature AlN may, for example, be AlN formed at temperatures between about 900-1000 degrees Celsius (° C.) and/or less than about 1000° C. Further, the low temperature AlN may, for example, be polycrystalline and/or may, for example, have an upper or top surface exhibiting a series of peaks and valleys. In other embodiments, the seed buffer layer 102 is or comprises high temperature AlN. The high temperature AlN may, for example, be AlN formed at temperatures between about 1000-1200° C. and/or greater than about 1000° C. Further, the high temperature AlN may, for example, be monocrystalline and/or may, for example, have an upper or top surface that is smooth. Between the low and high temperature AlN, the low temperature AlN may, for example, better match a lattice constant of the substrate 104, whereas the high temperature AlN may, for example, have better crystalline quality. Further, the seed buffer layer 102 has a high concentration of p-type dopants. The high doping concentration may, for example, be greater than about 1×10¹⁷ inverse cubic centimeters (cm⁻³), about 1×10¹⁸ cm⁻³, or about 1×10¹⁹ cm⁻³, and/or about 1×10¹⁷ to 1×10¹⁹ cm⁻³, 1×10¹⁷ to 1×10¹⁸ cm⁻³, or about 1×10¹⁸ to 1×10¹⁹ cm⁻³. The p-type dopants may be or comprise, for example, magnesium (e.g., Mg), carbon (e.g., C), iron (e.g., Fe), Zinc (e.g., Zn), or any combination of the foregoing. In some embodiments, the seed buffer layer 102 and the substrate 104 have the same doping type.

The seed buffer layer 102 induces band bending in the substrate 104. In at least some embodiments (e.g., where the substrate 104 is or comprises monocrystalline silicon), the band bending would induce formation of a 2DHG in the substrate 104 if the seed buffer layer 102 was undoped or intrinsic. The 2DHG would extend along an interface at which the seed buffer layer 102 and the substrate 104 contact and would increase substrate losses. However, because the seed buffer layer 102 is doped with p-type dopants, the holes in the seed buffer layer 102 are the majority carrier in the seed buffer layer 102 and repel holes that would form the 2DHG. By repelling holes that would form the 2DHG, the 2DHG is prevented from forming. This, in turn, prevents the 2DHG from negatively impacting (e.g., decreasing) a resistance of the substrate 104, reduces substrate losses, and enhances the PAE of the group III-V device.

In some embodiments, the concentration of p-type dopants in the seed buffer layer 102 is chosen so the concentration of holes in the seed buffer layer 102 matches the concentration in the 2DHG that would form absent the p-type dopants. In some embodiments, if the concentration of p-type dopants in the seed buffer layer 102 is too low (e.g., less than about 1×10¹⁷ cm⁻³), the 2DHG may not be fully depleted and substrate losses may be high. Further, in some embodiments, if the concentration of p-type dopants in the seed buffer layer 102 is too high (e.g., greater than about 1×10¹⁹ cm⁻³), the seed buffer layer 102 may, for example, impose too much stress (e.g., tensile stress) on the group III-V device, thereby causing cracking and device failure. In some embodiments, the seed buffer layer 102 has a thickness T_{sb} between about 30-300 nanometers, about 30-120 nanometers, about 120-210 nanometers, or about 210-300 nanometers. If the thickness T_{sb} is too low (e.g., less than about 30 nanometers), crystalline quality may, for example, be poor and formation of the seed buffer layer 102 may, for example, be difficult to control. If the thickness T_{sb} is too high (e.g., greater than 300 nanometers), the seed buffer layer 102 may, for example, impose too much stress (e.g., tensile stress) on the group III-V device, thereby causing cracking and device failure.

The heterojunction structure 108 overlies the buffer structure 106 and comprises a channel layer 110 and a barrier layer 112. The barrier layer 112 overlies the channel layer 110 and is polarized. The barrier layer 112 is polarized such that positive charge is shifted towards a lower or bottom surface of the barrier layer 112, and negative charge is shifted towards an upper or top surface of the barrier layer 112. The polarization may, for example, result from spontaneous polarization effects and/or piezoelectric polarization effects. The barrier layer 112 may be or comprise, for example, AlN, AlGaN, some other group III nitride, some other group III-V material, or any combination of the foregoing.

The channel layer 110 directly contacts the barrier layer 112 and is a semiconductor material with a band gap unequal to that of the barrier layer 112. Because of the unequal band gaps, the channel layer 110 and the barrier layer 112 define a heterojunction 114 at an interface at which the channel layer 110 and the barrier layer 112 directly contact. Further, because the barrier layer 112 is polarized, a two-dimensional electron gas (2DEG) 116 forms in the channel layer 110. The 2DEG 116 extends along the heterojunction 114 and has a high concentration of mobile electrons, such that the 2DEG 116 is conductive. The channel layer 110 may, for example, be or comprises undoped GaN, some other group III nitride, or some other group III-V material. In some embodiments, the channel layer 110 is undoped GaN, whereas the barrier layer 112 is or comprises undoped AlGaN. Further, the channel layer 110 may, for example, have a thickness between about 0.1-0.5 micrometers.

A first source/drain electrode 118 and a second source/drain electrode 120 overlie the channel layer 110 and extend into the barrier layer 112. In some embodiments, the first and second source/drain electrodes 118, 120 extend through the barrier layer 112 to the channel layer 110. Further, the first and second source/drain electrodes 118, 120 are electrically coupled to the 2DEG 116. In some embodiments, the first source/drain electrode 118 is a source for the group III-V device, and the second source/drain electrode 120 is a drain for the group III-V device. A gate electrode 122 overlies the barrier layer 112, laterally between the first and second source/drain electrodes 118, 120. The gate electrode 122 and the first and second source/drain electrodes 118, 120 are conductive and may be or comprise, for example, aluminum copper, aluminum, tungsten, copper, some other metal, doped polysilicon, some other conductive material, or any combination of the foregoing.

During use of the group III-V device, the gate electrode 122 generates an electric field that manipulates the continuity of the 2DEG 116 from the first source/drain electrode 118 to the second source/drain electrode 120. For example, when the gate electrode 122 is biased with a voltage more than a threshold voltage, the gate electrode 122 may generate an electric field depleting an underlying portion of the 2DEG 116 of mobile electrons and breaking the continuity of the 2DEG 116 from the first source/drain electrode 118 to the second source/drain electrode 120. As another example, when the gate electrode 122 is biased with a voltage less than the threshold voltage, the 2DEG 116 may be continuous from the first source/drain electrode 118 to the second source/drain electrode 120.

In some embodiments, the buffer structure 106 further comprises a graded buffer layer 124 and/or an isolation buffer layer 126 between the heterojunction structure 108 and the seed buffer layer 102. The graded buffer layer 124 includes a stack of grading buffer layers. For example, the graded buffer layer 124 may comprise a first grading buffer layer 124a, a second grading buffer layer 124b overlying the first grading buffer layer 124a, and a third grading buffer layer 124c overlying the second grading buffer layer 124b. Individual lattice constants of the grading buffer layers increase or decrease from a top of the graded buffer layer 124 to a bottom of the graded buffer layer 124 to grade a lattice constant of the graded buffer layer 124 and to lessen or eliminate lattice mismatch from the seed buffer layer 102 to a layer (e.g., the isolation buffer layer 126) overlying the graded buffer layer 124. The graded buffer layer 124 and hence the grading buffer layers may be or comprise, for example, aluminum gallium nitride, some other group III nitride, some other group III-V material, or any combination of the foregoing.

In some embodiments, the grading buffer layers share a common set of elements (e.g., aluminum, gallium, and nitride) and have individual amounts of the elements. In some embodiments, the individual amounts for at least one of the elements increase or decrease from the top of the graded buffer layer 124 to the bottom of the graded buffer layer 124 to vary the individual lattice constants of the grading buffer layers and to grade the lattice constant of the graded buffer layer 124. For example, the first grading buffer layer 124a may be or comprise AlₓGa₁₋ₓN and may have a first lattice constant, the second grading buffer layer 124b may be or comprise Al_{y}Ga_{1-y}N and may have a second lattice constant greater than the first lattice constant, and the third grading buffer layer 124c may be or comprise Al_{z}Ga_{1-z}N and may have a third lattice constant greater than the second lattice constant, where x, y, and z are respectively about 0.6-0.8, about 0.4-0.6, and about 0.1-0.3. In some embodiments, the first grading buffer layer 124a has a thickness between about 200-800 nanometers, the second grading buffer layer 124b has a thickness between about 300-1000 nanometers, the third grading buffer layer 124c has a thickness between about 500-2000 nanometers, or any combination of the foregoing.

The isolation buffer layer 126 overlies the seed buffer layer 102 and, where present, the graded buffer layer 124. In some embodiments, the isolation buffer layer 126 has a thickness between about 0.5-5.0 micrometers. The isolation buffer layer 126 is a semiconductor material doped with a high concentration of p-type dopants so as to have a high resistance. The high resistance may, for example, be a resistance higher than that of the channel layer 110. The p-type dopants may be or comprise Mg, C, Fe, Zn, or any combination of the foregoing. The high doping concentration may, for example, be greater than about 1×10¹⁸ cm⁻³, about 1×10¹⁹ cm⁻³, or about 1×10²⁰ cm⁻³, and/or about 1×10¹⁸ to 1×10²⁰ cm⁻³, 1×10¹⁸ to 1×10¹⁹ cm⁻³, or about 1×10¹⁹ to 1×10²⁰ cm⁻³. The high resistance of the isolation buffer layer 126 allows the isolation buffer layer 126 to act as “back barrier” for the channel layer 110 to reduce substrate losses and to increase the soft breakdown voltage of the group III-V device. The isolation buffer layer 126 may be or comprise, for example, doped GaN, some other group III nitride, some other group III-V material, or any combination of the foregoing.

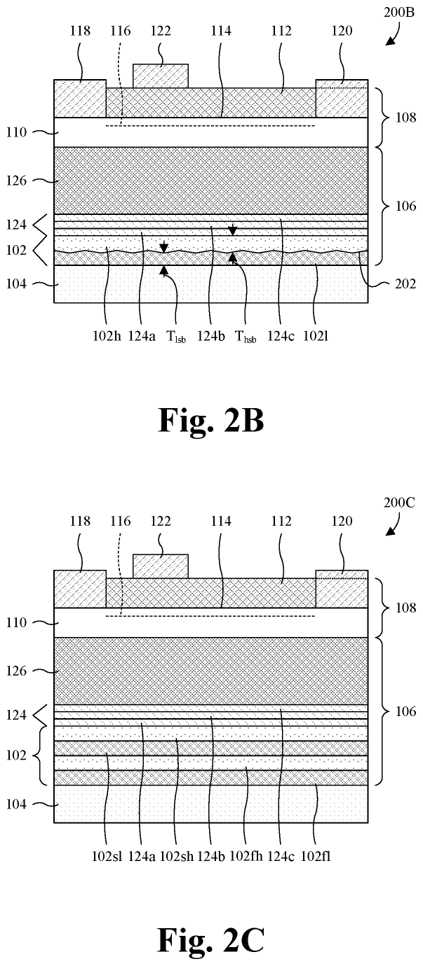

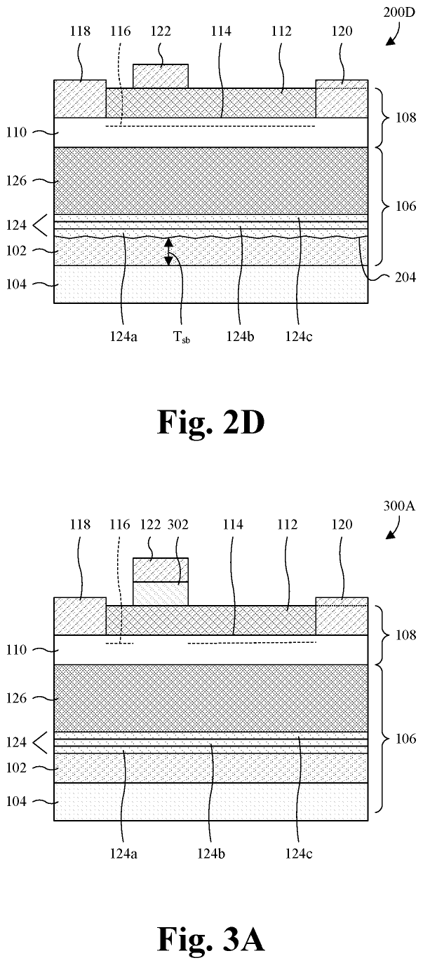

With reference to FIG. 2A, a cross-sectional view 200A of some alternative embodiments of the group III-V device of FIG. 1 is provided in which the seed buffer layer 102 comprises a low temperature seed buffer layer 102l and a high temperature seed buffer layer 102h overlying the low temperature seed buffer layer 102l. The low and high temperature seed buffer layers 102l, 102h may be or comprise, for example, AlN, some other group III nitride, or some other group III-V material. In some embodiments, the low temperature seed buffer layer 102l has a first ratio of group III atoms to group V atoms, and the high temperature seed buffer layer 102h has a second ratio of group III atoms to group V atoms that is different than the first ratio. The low temperature seed buffer layer 102l is formed at low temperatures, whereas the high temperature seed buffer layer is formed at high temperatures. The low temperatures may, for example, be about 900-1000° C. and/or less than about 1000° C. The high temperatures may, for example, be about 1000-1200° C. and/or greater than about 1000° C. In some embodiments, the low and high temperature seed buffer layers 102l, 102h are the same material (e.g., AlN). In some embodiments, the low temperature seed buffer layer 102l is or comprises low temperature AlN and/or the high temperature seed buffer layer 102h is or comprises high temperature AlN. The low temperature AlN may, for example, be as described with regard to FIG. 1, and/or the high temperature AlN may, for example, be described with regard to FIG. 1.

The low and high temperature seed buffer layers 102l, 102h have high concentrations of p-type dopants to achieve high resistances. The p-type dopants may, for example, be or comprise Mg, C, Fe, Zn, or any combination of the foregoing. The high doping concentrations may, for example, be greater than about 1×10¹⁷ cm⁻³, about 1×10¹⁸ cm⁻³, or about 1×10¹⁹ cm⁻³, and/or about 1×10¹⁷ to 1×10¹⁹ cm⁻³, 1×10¹⁷ to 1×10¹⁸ cm⁻³, or about 1×10¹⁸ to 1×10¹⁹ cm⁻³. Due to the high doping concentrations, the low and high temperature seed buffer layers 102l, 102h do not induce formation of a 2DHG in the substrate 104. As such, substrate losses are minimized and PAE of the group III-V device is enhanced.

In some embodiments, the low temperature seed buffer layer 102l has a low temperature thickness T_{lsb} that is about 20-80 nanometers, about 20-50 nanometers, or about 50-80 nanometers, and/or that is less than about 50 or 80 nanometers. The low temperature thickness T_{lsb} may, for example, be limited (e.g., to less than about 80 nanometers) due to difficulties growing the low temperature seed buffer layer 102l directly on the substrate 104. Further, if the low temperature thickness T_{lsb} is too low (e.g., less than about 20 nanometers), formation of the low temperature seed buffer layer 102l may, for example, be difficult to control. In some embodiments, the high temperature seed buffer layer 102h has a high temperature thickness T_{hsb} that is about 50-300 nanometer, about 50-175 nanometers, or about 175-300 nanometers, and/or that is less than about 175 or 300 nanometers. If the high temperature thickness T_{hsb} is too low (e.g., less than about 50 nanometers), crystalline quality may, for example, be poor and formation of high temperature seed buffer layer 102h may, for example, be difficult to control. If the high temperature thickness T_{hsb} is too high (e.g., greater than 300 nanometers), the high temperature seed buffer layer 102h may, for example, impose too much stress (e.g., tensile stress) on the group III-V device, thereby causing cracking and device failure.

With reference to FIG. 2B, a cross-sectional view 200B of some alternative embodiments of the group III-V device of FIG. 2A is provided in which an interface 202 at which the low and high temperature seed buffer layers 102l, 102h contact is rough. For example, the interface 202 may have a series of peaks and valleys. In some embodiments, the series of peaks and valleys is periodic. In other embodiments, the series of peaks and valleys is irregular. In some embodiments, the interface 202 has a saw-toothed profile. The interface 202 may, for example, be rough due to formation of the low and high temperature seed buffer layers 102l, 102h respectively at low and high temperatures. In some embodiments, forming the low temperature seed buffer layer 102l at low temperatures may form the low temperature seed buffer layer 102l in a three-dimensional (3D) growth mode, whereby an upper or top surface of the low temperature seed buffer layer 102l may have a series of peaks and valleys. Further, in some embodiments, forming the high temperature seed buffer layer 102h at high temperatures may, for example, form the high temperature seed buffer layer 102h in a two-dimensional (2D) growth mode, whereby an upper or top surface of the high temperature seed buffer layer 102h may be flat or relatively flat compared to the low temperature seed buffer layer 102l.

With reference to FIG. 2C, a cross-sectional view 200C of some alternative embodiments of the group III-V device of FIG. 1 is provided in which the seed buffer layer 102 comprises multiple low temperature seed buffer layers and multiple high temperature seed buffer layers alternatingly stacked. For example, the seed buffer layer 102 may comprise a first low temperature seed buffer layer 102fl, a first high temperature seed buffer layer 102fh overlying the first low temperature seed buffer layer 102fl, a second low temperature seed buffer layer 102s1 overlying the first high temperature seed buffer layer 102fh, and a second high temperature seed buffer layer 102sh overlying the second low temperature seed buffer layer 102s1. The low temperature seed buffer layers (e.g., 102fl and 102s1) are as the low temperature seed buffer layer 102l of FIG. 2A is described, and the high temperature seed buffer layers (e.g., 102fh and 102sh) are as the high temperature seed buffer layer 102h of FIG. 2A is described.

While FIG. 2C illustrates two low temperature seed buffer layers (e.g., 102fl and 102s1) and two high temperature seed buffer layers (e.g., 102fh and 102sh), more low temperature seed buffer layers and/or more high temperature seed buffer layers is/are amenable in other embodiments. In such other embodiments, the alternating pattern of low and high temperature seed buffer layers illustrated in FIG. 2C continues for the one or more additional low and/or high temperature seed buffer layers. Further, while the upper or top surfaces of the low temperature seed buffer layers are illustrated as contacting the lower or bottom surfaces of the high temperature seed buffer layers at interfaces that are flat or substantially flat, it is to be appreciated that the interfaces may be rough in other embodiments. The interface 202 of FIG. 2B may, for example, be representative of such rough interfaces.

With reference to FIG. 2D, a cross-sectional view 200D of some alternative embodiments of the group III-V device of FIG. 1 is provided in which an interface 204 at which the seed buffer layer 102 and the graded buffer layer 124 contact is rough. For example, the interface 204 may have a series of peaks and valleys. The series of peaks and valleys may, for example, be periodic or irregular. In some embodiments, the interface 204 has a saw-toothed profile. The interface 204 may, for example, be rough due to formation of the seed buffer layer 102 at low temperatures. In some embodiments, forming the seed buffer layer 102 at low temperatures forms the seed buffer layer 102 in a 3D growth mode, whereby an upper or top surface of the seed buffer layer 102 may, for example, have a series of peaks and valleys. In some embodiments, the seed buffer layer 102 is or comprises low temperature AlN, which may, for example, be as described with regard to FIG. 2A.

While the substrate 104, the seed buffer layer 102, and the isolation buffer layer 126 are described as being doped with p-type dopants in at least some embodiments of FIGS. 1 and 2A-2D, it is to be appreciated that n-type dopants may alternatively be used for the substrate 104, the seed buffer layer 102, the isolation buffer layer 126, or any combination of the foregoing in other embodiments. While the graded buffer layer 124 is described and illustrated as having three grading buffer layers in at least some embodiments of FIGS. 1 and 2A-2D, it is to be appreciated that the graded buffer layer 124 may have more or less grading buffer layers in other embodiments.

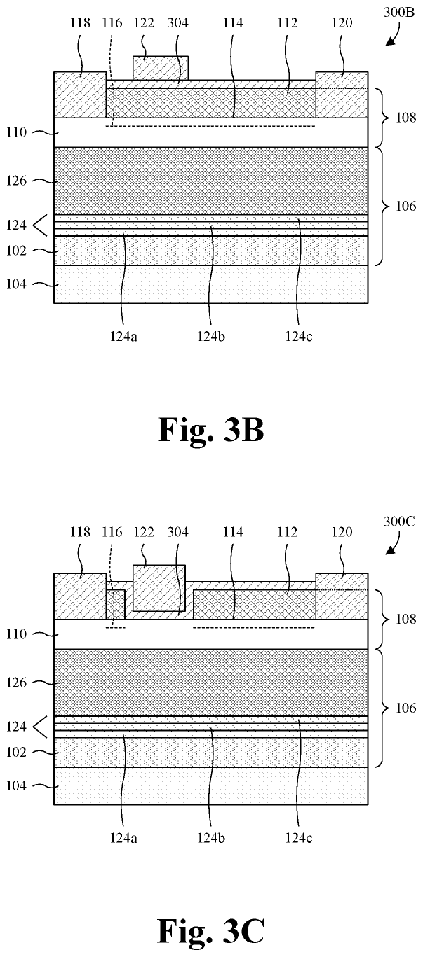

With reference to FIG. 3A, a cross-sectional view 300A of some alternative embodiments of the group III-V device of FIG. 1 is provided in which a group III-V gate layer 302 separates the gate electrode 122 from the barrier layer 112. In some embodiments, the group III-V gate layer 302 is completely covered by the gate electrode 122 and/or has the same top layout (not visible within the cross-sectional view 300A) as the gate electrode 122. The group III-V gate layer 302 is doped with n-type or p-type dopants and may, for example, be GaN, some other group III nitride, some other group III-V material, or any combination of the foregoing.

The group III-V gate layer 302 is doped and/or polarized so as to deplete an underlying portion of the 2DEG 116 in the absence of external electric fields and/or electric fields from the gate electrode 122. Therefore, when the gate electrode 122 is biased with a voltage less than a threshold voltage, the 2DEG 116 is discontinuous from the first source/drain electrode 118 to the second source/drain electrode 120. Further, when the gate electrode 122 is biased with a voltage more than the threshold voltage, the gate electrode 122 generates an electric field enhancing the underlying portion of the 2DEG 116 so the 2DEG 122 is continuous from the first source/drain electrode 118 to the second source/drain electrode 120 electrode. In some embodiments, the group III-V device is an enhancement mode HEMT.

With reference to FIG. 3B, a cross-sectional view 300B of some alternative embodiments of the group III-V device of FIG. 1 is provided in which a gate dielectric layer 304 separates the gate electrode 122 from the barrier layer 112. In some embodiments, the gate dielectric layer 304 extends from the first source/drain electrode 118 to the second source/drain electrode 120. The gate dielectric layer 304 may be or comprise, for example, silicon oxide, some other oxide, some other dielectric, or any combination of the foregoing.

In the absence of external electric fields and/or electric fields from the gate electrode 122, the 2DEG 116 is continuous from the first source/drain electrode 118 to the second source/drain electrode 120. Therefore, when the gate electrode 122 is biased with a voltage less than a threshold voltage, the 2DEG 116 is continuous from the first source/drain electrode 118 to the second source/drain electrode 120. Further, when the gate electrode 122 is biased with a voltage more than the threshold voltage, the gate electrode 122 generates an electric field depleting a portion of the 2DEG 116 underlying the gate electrode 122 so the 2DEG 122 is discontinuous from the first source/drain electrode 118 to the second source/drain electrode 120. In some embodiments, the group III-V device is a depletion mode metal-insulator-semiconductor field-effect transistor (MISFET).

With reference to FIG. 3C, a cross-sectional view 300C of some alternative embodiments of the group III-V device of FIG. 3B is provided in which the gate dielectric layer 304 and the gate electrode 122 extend through the barrier layer 112. The gate dielectric layer 304 extends through the barrier layer 112 to the channel layer 110, and the gate electrode 122 is recessed into the barrier layer 112.

Because the gate dielectric layer 304 and the gate electrode 122 extend through the barrier layer 112, the channel layer 110 is uncovered by the barrier layer 112 at the gate electrode 122. Further, because it's the barrier layer 112 that attracts mobile electrons and forms the 2DEG 116, the 2DEG 116 is depleted at the gate electrode 122 in the absence of external electric fields and/or electric fields from the gate electrode 122. Therefore, when the gate electrode 122 is biased with a voltage less than a threshold voltage, the 2DEG 116 is discontinuous from the first source/drain electrode 118 to the second source/drain electrode 120. When the gate electrode 122 is biased with a voltage more than the threshold voltage, the gate electrode 122 generates an electric field enhancing the 2DEG 116 at the gate electrode 122 so the 2DEG 122 is continuous from the first source/drain electrode 118 to the second source/drain electrode 120. In some embodiments, the group III-V device is an enhancement mode MISFET.

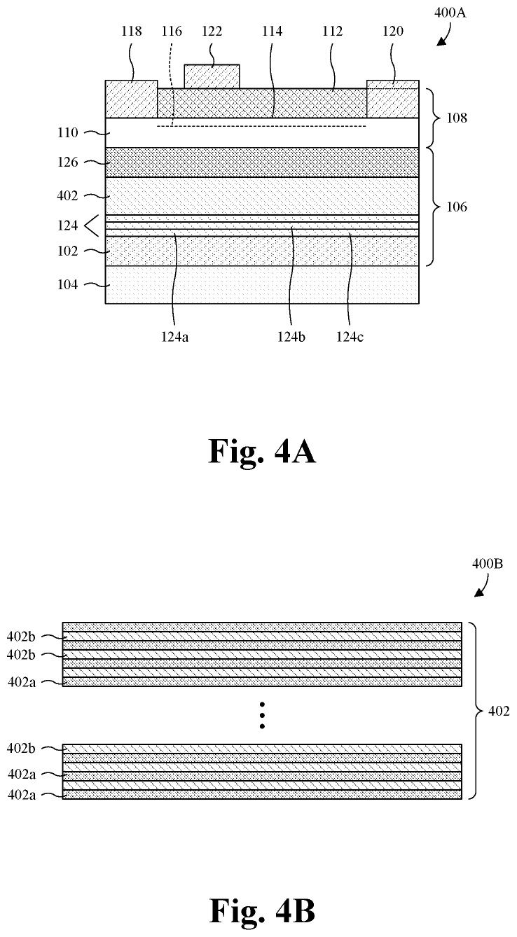

With reference to FIG. 4A, a cross-sectional view 400A of some alternative embodiments of the group III-V device of FIG. 1 is provided in which the buffer structure 106 further includes a strained super lattice (SLS) buffer layer 402 between the isolation buffer layer 126 and the graded buffer layer 124. The SLS buffer layer 402 blocks silicon from the substrate 104 from diffusing or otherwise moving to the isolation buffer layer 126. Such silicon would reduce a resistance of the isolation buffer layer 126 and would increase a soft breakdown voltage of the group III-V device. Further, the SLS buffer layer 402 releases stress of the isolation buffer layer 126. For example, the isolation buffer layer 126 may be under tensile stress, and the SLS buffer layer 402 may produce compressive stress counteracting the tensile stress. The tensile stress could lead to substrate cracking and/or could negatively impact performance (e.g., dynamic ON resistance) of the group III-V device.

With reference to FIG. 4B, a cross-sectional view 400B of some embodiments of the SLS buffer layer 402 of FIG. 4A is provided. The SLS buffer layer 402 comprises a plurality of first group III-V layers 402a and a plurality of second group III-V layers 402b. For ease of illustration, only some of the first group III-V layers 402a are labeled 402a and only some of the second group III-V layers 402b are labeled 402b. The first and second group III-V layers 402a, 402b are alternatingly stacked, and the first group III-V layers 402a have a different lattice constant than the second group III-V layers 402b. For example, the first group III-V layers 402a may be or comprise AlN or some other group III-V material, and the second group III-V layers 402b may be or comprise GaN or some other group III-V material, or vice versa.

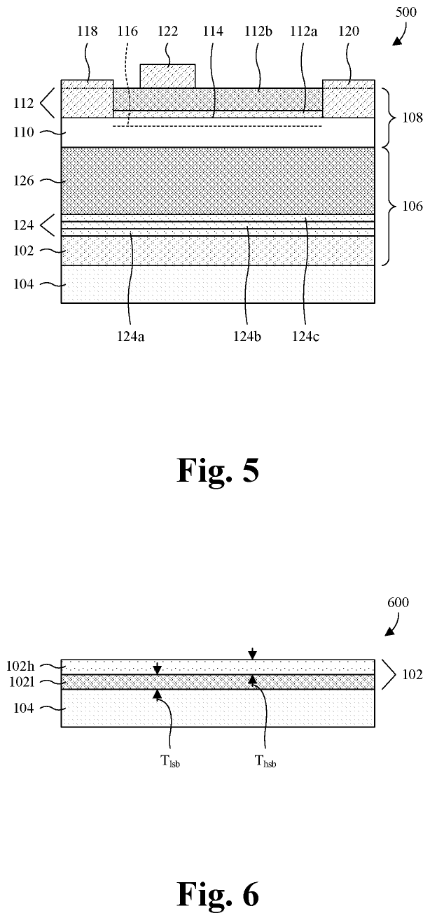

With reference to FIG. 5, a cross-sectional view 500 of some alternative embodiments of the group III-V device of FIG. 1 is provided in which the barrier layer 112 comprises a first barrier layer 112a and a second barrier layer 112b overlying the first barrier layer 112a. The first barrier layer 112a may be or comprise, for example, AlN or some other group III nitride, and/or the second barrier layer 112b may be or comprise, for example, AlₓG₁₋ₓN or some other group III nitride, where x is an integer between about 0.1-0.3. The first barrier layer 112a may, for example, have a thickness between about 0.5-1.5 nanometers, and/or the second barrier layer 112b may, for example, have a thickness between about 10-40 nanometers.

While FIGS. 3A-3C, 4A, and 5 are illustrated using embodiments of the seed buffer layer 102 in FIG. 1, it is to be appreciated that embodiments of the seed buffer layer 102 in FIGS. 2A-2D may alternatingly be used within FIGS. 3A-3C, 4A, and 5. While FIGS. 2A-2D, 3A-3C, and 4A are illustrated using embodiments of the barrier layer 112 in FIG. 1, it is to be appreciated that embodiments of the barrier layer 112 in FIG. 5 may alternatingly be used within FIGS. 2A-2D, 3A-3C, and 4A. While FIGS. 2A-2D, 3A-3C, and 5 are illustrated using embodiments of the buffer structure 106 in FIG. 1, it is to be appreciated that embodiments of buffer structure 106 in FIG. 4A may alternatingly be used within FIGS. 2A-2D, 3A-3C, and 5.

With reference to FIGS. 6-11, a series of cross-sectional views 600-1100 of some embodiments of a method for forming a group III-V device comprising a seed buffer layer 102 that is doped is provided. The method may, for example, form embodiments of the group III-V device in any one of FIGS. 1, 2A-2D, 3A-3C, 4A, and 5. Further, while FIGS. 6-11 are described with reference to the method, it will be appreciated that the structures shown in FIGS. 6-11 are not limited to the method and may stand alone without the method.

As illustrated by the cross-sectional view 600 of FIG. 6, a substrate 104 is provided. In some embodiments, the substrate 104 is or comprises monocrystalline silicon or some other silicon, and/or has a crystalline orientation of (111) or some other crystalline orientation. Further, in some embodiments, the substrate 104 has a high resistance to reduce substrate losses. The high resistance may, for example, be greater than about 1, 1.8, or 3 kΩ/cm, and/or may, for example, be between about 1-1.8 kΩ/cm, or about 1.8-3 kΩ/cm. Further, in some embodiments, the substrate 104 is doped with p-type dopants to achieve the high resistance.

Also illustrated by the cross-sectional view 600 of FIG. 6, a seed buffer layer 102 is epitaxially formed on the substrate 104. The seed buffer layer 102 comprises a low temperature seed buffer layer 102l and a high temperature seed buffer layer 102h overlying the low temperature seed buffer layer 102l. The low and high temperature seed buffer layers 102l, 102h are or comprise AlN, some other group III nitride, some other group III-V material, or any combination of the foregoing. Further, the low and high temperature seed buffer layers 102l, 102h have a high concentration of p-type dopants. The p-type dopants may be or comprise, for example, Mg, C, Fe, Zn, or any combination of the foregoing. The high doping concentration may, for example, be greater than about 1×10¹⁷ cm⁻³, about 1×10¹⁸ cm⁻³, or about 1×10¹⁹ cm⁻³, and/or may, for example, be about 1×10¹⁷ to 1×10¹⁹ cm⁻³, 1×10¹⁷ to 1×10¹⁸ cm⁻³, or about 1×10¹⁸ to 1×10¹⁹ cm⁻³. In some embodiments, the low and high temperature seed buffer layers 102l, 102h are or comprise the same material (e.g., AlN), have the same dopants (e.g., Mg), have the same concentration of dopants, or any combination of the foregoing. In some embodiments, the low temperature seed buffer layer 102l has a first ratio of group III atoms to group V atoms, and the high temperature seed buffer layer 102h has a second ratio of group III atoms to group V atoms that is different than the first ratio. In some embodiments, the low temperature seed buffer layer 102l has a thickness T_{lsb} between about 20-80 nanometers, about 20-40 nanometers, or about 40-80 nanometers, and/or the high temperature seed buffer layer 102h has a thickness T_{hsb} between about 50-300 nanometers, about 50-175 nanometers, or about 175-300 nanometers.

In some embodiments, a process for forming the seed buffer layer 102 comprises epitaxially forming the low temperature seed buffer layer 102l on the substrate 104, and epitaxially forming the high temperature seed buffer layer 102h on the low temperature seed buffer layer 102l. The low and high temperature seed buffer layers 102l, 102h are epitaxially formed by, for example, molecular beam epitaxy (MBE), metalorganic vapor phase epitaxy (MOVPE), some other vapor phase epitaxy (VPE), liquid phase epitaxy (LPE), some other suitable epitaxial process, or any combination of the foregoing. In some embodiments, the low and high temperature seed buffer layers 102l, 102h are formed by the same epitaxial process (e.g., MOVPE). In some embodiments, the low temperature seed buffer layer 102l and/or the high temperature seed buffer layer 102h is/are formed while simultaneously being doped with the p-type dopants (e.g., Mg, C, Fe, or Zn). For example, the low and/or high temperature seed buffer layer 102l, 102h may be formed within a reactor by MOVPE while bis-cyclopentadienyl magnesium (Cp₂Mg) is injected into the reactor, thereby forming the low and/or high temperature seed buffer layer 102l, 102h doped with Mg dopants. In other embodiments, the low temperature seed buffer layer 102l and/or the high temperature seed buffer layer 102h is/are doped after being formed.

The low temperature seed buffer layer 102l is formed at low temperatures, whereas the high temperature seed buffer layer 102h is formed at high temperatures greater than the low temperatures. In some embodiments, the low temperatures are about 900-1000° C., about 900-950° C., or about 950-1000° C., and/or are less than about 900, 950, or 1000° C. In some embodiments, the high temperatures are about 1000-1200° C., about 1000-1100° C., or about 1100-1200° C., and/or are greater than about 1000, 1100, or 1200° C. In some embodiments, forming the low temperature seed buffer layer 102l at the low temperatures promotes formation of the low temperature seed buffer layer 102l in a 3D growth mode. In some embodiments, the 3D growth mode results in formation of the low temperature seed buffer layer 102l with poor crystal quality and/or an upper or top surface that includes a series of peaks and valleys. For example, an upper or top surface of the low temperature seed buffer layer 102l may have a saw-toothed profile due to the 3D growth mode. An example of this is shown in FIG. 2B. In some embodiments, forming the high temperature seed buffer layer 102h at the high temperatures promotes formation of the high temperature seed buffer layer 102h in a 2D growth mode. In some embodiments, the 2D growth mode results in formation of the high temperature seed buffer layer 102h with high crystal quality and/or an upper or top surface that is relatively smooth compared to that of the low temperature seed buffer layer 102l.

Due to the high concentration of p-type dopants, the seed buffer layer 102 does not induce induces formation of a 2DHG in the substrate 104, along an interface at which the seed buffer layer 102 and the substrate 104 contact. The p-type dopants of the seed buffer layer 102 have a positive charge that repels mobile holes in the substrate 104 and prevents the 2DHG from forming. In some embodiments, the doping concentration of the p-type dopants is selected so as to fully deplete the 2DHG. If the doping concentration is too low (e.g., less than about 1×10¹⁷ cm⁻³), the 2DHG won't be fully depleted. If the doping concentration is too high (e.g., greater than about 1×10¹⁹ cm⁻³), stress on the group III-V device may be too high and the group III-V device may crack and fail. By preventing the 2DHG from forming, a resistance of the substrate 104 remains high and is not reduced by the 2DHG. As such, substrates losses are minimized and PAE of the group III-V device is enhanced.

While FIG. 6 illustrates formation of both the low temperature seed buffer layer 102l and the high temperature seed buffer layer 102h, one of the low and high temperature seed buffer layers 102l, 102h may be omitted (i.e., not formed) in other embodiments. In such other embodiments, the seed buffer layer 102 and the remaining one of the low and high temperature seed buffer layers 102l, 102h may be one and the same. Further, while FIG. 6 illustrates formation of the low and high temperature seed buffer layers 102l, 102h each once, the low temperature seed buffer layer 102l may be formed multiple times and/or the high temperature seed buffer layer 102h may be formed multiple times in other embodiments. In such other embodiments, the seed buffer layer 102 alternates between low and high temperature seed buffer layers, an example of which is illustrated and described with regard to FIG. 2C.

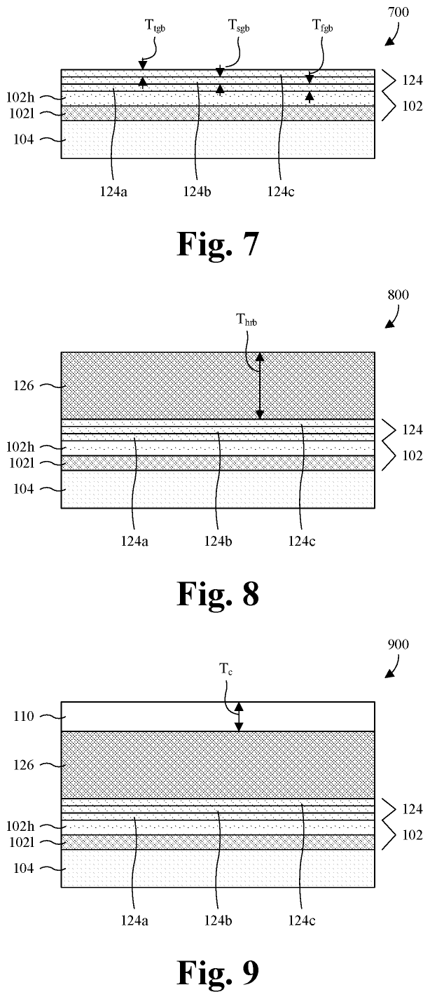

As illustrated by the cross-sectional view 700 of FIG. 7, a graded buffer layer 124 is epitaxially formed over the seed buffer layer 102. The graded buffer layer 124 includes a stack of grading buffer layers. For example, the graded buffer layer 124 may comprise a first grading buffer layer 124a, a second grading buffer layer 124b overlying the first grading buffer layer 124a, and a third grading buffer layer 124c overlying the second grading buffer layer 124b. Individual lattice constants of the grading buffer layers increase or decrease from a top of the graded buffer layer 124 to a bottom of the graded buffer layer 124 to grade a lattice constant of the graded buffer layer 124 and to lessen or eliminate lattice mismatch from the seed buffer layer 102 to a layer hereafter formed on the graded buffer layer 124. The graded buffer layer 124 and hence the grading buffer layers may be or comprise, for example, aluminum gallium nitride, some other group III nitride, some other group III-V nitride, or any combination of the foregoing.

In some embodiments, the grading buffer layers share a common set of elements and have individual amounts of the elements. In some embodiments, the individual amounts for at least one of the elements increase or decrease from the top of the graded buffer layer 124 to the bottom of the graded buffer layer 124 to vary the individual lattice constants of the grading buffer layers and to grade the lattice constant of the graded buffer layer 124. For example, the first grading buffer layer 124a may be or comprise AlₓGa₁₋ₓN, the second grading buffer layer 124b may be or comprise Al_{y}Ga_{1-y}N, and the third grading buffer layer 124c may be or comprise Al_{z}Ga_{1-z}N, where x is about 0.6-0.8, y is about 0.4-0.6, and z is about 0.1-0.3. In some embodiments, the first grading buffer layer 124a has a thickness T_{fgb} between about 200-800 nanometers, 200-500 nanometers, or about 500-800 nanometers. In some embodiments, the second grading buffer layer 124b has a thickness T_{sgb} between about 300-1000 nanometers, about 300-650 nanometers, or about 650-1000 nanometers. In some embodiments, the third grading buffer layer 124c has a thickness T_{tgb} between about 500-2000 nanometers, about 500-1250 nanometers, or about 1250-2000 nanometers.

In some embodiments, a process for forming the graded buffer layer 124 comprises sequentially forming the grading buffer layers stacked over the seed buffer layer 102. For example, the first grading buffer layer 124a may be formed over the seed buffer layer 102, the second grading buffer layer 124b may be formed over the first grading buffer layer 124a, and the third grading buffer layer 124c may be formed over the second grading buffer layer 124b. The graded buffer layer 124 may, for example, be formed by MBE, MOVPE, some other VPE, LPE, some other suitable epitaxial process, or any combination of the foregoing. In some embodiments, the graded buffer layer 124 is formed at temperatures between 1000-1200° C., about 1000-1100° C., or about 1100-1200° C. In some embodiments, the seed buffer layer 102 is used as a seed for epitaxially forming the graded buffer layer 124.

As illustrated by the cross-sectional view 800 of FIG. 8, an isolation buffer layer 126 is epitaxially formed over the graded buffer layer 124. The isolation buffer layer 126 is a semiconductor material doped with a high concentration of p-type dopants so as to have a high resistance. The high resistance may, for example, be high relative to a channel layer hereafter formed. The p-type dopants may be or comprise, for example, Mg, C, Fe, Zn, or any combination of the foregoing. The high doping concentration may, for example, be greater than about 1×10¹⁸ cm⁻³, about 1×10¹⁹ cm⁻³, or about 1×10²⁰ cm⁻³, and/or may, for example, be about 1×10¹⁸ to 1×10²⁰ cm⁻³, 1×10¹⁸ to 1×10¹⁹ cm⁻³, or about 1×10¹⁹ to 1×10²⁰ cm⁻³. In some embodiments, the high doping concentration exceeds those of the low and high temperature seed buffer layers 102l, 102h. The isolation buffer layer 126 may be or comprise, for example, doped GaN, some other group III nitride, some other group III-V material, or any combination of the foregoing. In some embodiments, the isolation buffer layer 126 has a thickness T_{hrb} of about 0.5-5.0 micrometers, about 0.5-2.75 micrometers, or about 2.75-5.0 micrometers.

In some embodiments, the isolation buffer layer 126 is formed by MBE, MOVPE, some other VPE, LPE, some other suitable epitaxial process, or any combination of the foregoing. In some embodiments, the isolation buffer layer 126 is formed at temperatures of about 900-1100° C., about 900-1000° C., or about 1000-1100° C. In some embodiments, the isolation buffer layer 126 is formed while simultaneously being doped with the dopants (e.g., Mg, C, or Fe). In other embodiments, the isolation buffer layer 126 is doped after being formed. In some embodiments, the seed buffer layer 102 (e.g., the low temperature seed buffer layer 102l and/or the high temperature seed buffer layer 102h) is doped with Mg dopants, whereas the isolation buffer layer 126 is doped with C dopants.

While not shown, a SLS buffer layer may be epitaxially formed between the forming of the isolation buffer layer 126 and the forming of the graded buffer layer 124 in other embodiments. An example of the SLS buffer layer is as illustrated and described with regard to the SLS buffer layer 402 of FIGS. 4A and 4B. The SLS buffer layer may, for example, release stress of the isolation buffer layer 126. For example, the isolation buffer layer 126 may be under tensile stress, and the SLS buffer layer may produce compressive stress counteracting the tensile stress. Absent the SLS buffer layer, the tensile stress could lead to wafer cracking and/or could negatively impact performance (e.g., dynamic ON resistance) of the group III-V device.

As illustrated by the cross-sectional view 900 of FIG. 9, a channel layer 110 is epitaxially formed over the isolation buffer layer 126. The channel layer 110 is undoped and/or has a low doping concentration less than about 1×10¹⁷ cm⁻³, 1×10¹⁶ cm⁻³, or 1×10¹⁵ cm⁻³ In some embodiments, the isolation buffer layer 126 is doped with carbon to a concentration greater than about 1×10¹⁸ cm⁻³, and the channel layer 110 has a doping concentration of carbon less than about 1×10¹⁷ cm⁻³. The channel layer 110 may be or comprise, for example, GaN, some other group III nitride, or some other group III-V material. In some embodiments, the channel layer 110 has a thickness T_{c} of about 0.1-0.5 micrometers, about 0.1-0.35 micrometers, about 0.35-0.5 micrometers, or about 0.25 micrometers.

In some embodiments, the channel layer 110 is formed by MBE, MOVPE, some other VPE, LPE, some other suitable epitaxial process, or any combination of the foregoing. In some embodiments, the channel layer 110 is formed at temperatures of about 1000-1200° C., about 1000-1100° C., or about 1100-1200° C. In some embodiments, the channel layer 110 is formed undoped and small amounts of dopants subsequently diffuse into the channel layer 110 from neighboring layers (e.g., the isolation buffer layer 126).

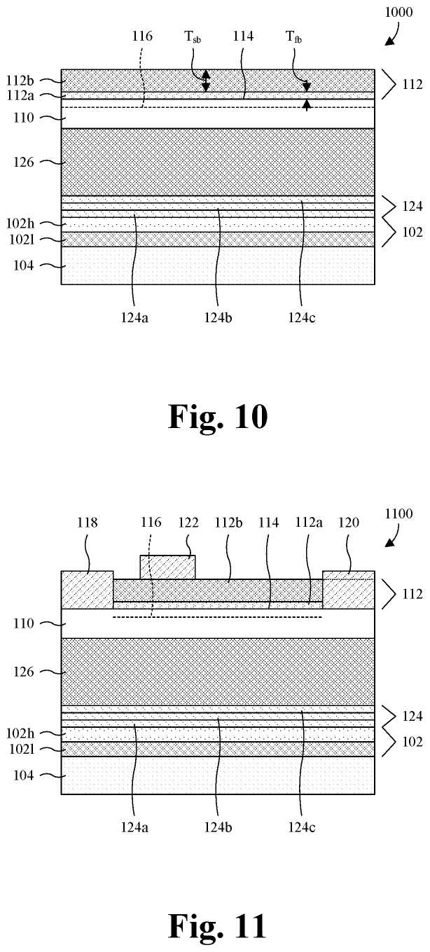

As illustrated by the cross-sectional view 1000 of FIG. 10, a barrier layer 112 is epitaxially formed directly on the channel layer 110. The barrier layer 112 is a semiconductor material with a band gap unequal to that of the channel layer 110, whereby forming the barrier layer 112 directly on the channel layer 110 defines a heterojunction 114. Further, the barrier layer 112 is polarized such that positive charge is shifted towards a lower or bottom surface of the barrier layer 112, and negative charge is shifted towards an upper or top surface of the barrier layer 112. The polarization causes a 2DEG 116 to form in the channel layer 110, along the heterojunction 114. The 2DEG 116 has a high concentration of mobile electrons, such that it is conductive. The barrier layer 112 may be or comprise, for example, AlN, AlGaN, some other group III nitride, some other group III-V material, or any combination of the foregoing.

In some embodiments, the barrier layer 112 comprises a first barrier layer 112a and a second barrier layer 112b overlying the first barrier layer 112a. The first barrier layer 112a may be or comprise, for example, AlN or some other group III-V material, and/or the second barrier layer 112b may be or comprise, for example, AlGaN or some other group III-V material. In some embodiments, the second barrier layer 112b is AlₓGa₁₋ₓN, where x is about 0.1-0.3, about 0.1-0.2, or about 0.2-0.3. In some embodiments, the first barrier layer 112a has a first barrier thickness T_{fb} less than a second barrier thickness T_{sb} of the second barrier layer 112b. The first barrier thickness T_{fb} may, for example, be about 0.5-1.5 nanometers, about 0.5-1.0 nanometers, or about 1.0-1.5 nanometers. The second barrier thickness T_{sb} may, for example, be about 10-40 nanometers, about 10-25 nanometers, or about 25-40 nanometers.

In some embodiments, the barrier layer 112 is epitaxially formed by MBE, MOVPE, some other VPE, LPE, some other suitable epitaxial process, or any combination of the foregoing. In some embodiments, a process for forming the barrier layer 112 comprises epitaxially forming the first barrier layer 112a, and subsequently epitaxially forming the second barrier layer 112b on the first barrier layer 112b. In some embodiments, the barrier layer 112 and hence the first and second barrier layers 112a, 112b are formed at temperatures of about 1000-1200° C., about 1000-1100° C., or about 1100-1200° C.

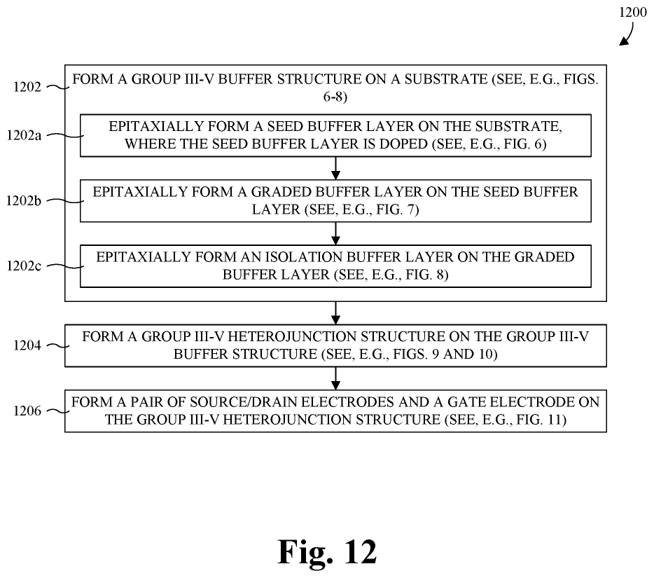

As illustrated by the cross-sectional view 1100 of FIG. 11, a first source/drain electrode 118 and a second source/drain electrode 120 are formed extending into the barrier layer 112. In some embodiments, the first and second source/drain electrodes 118, 120 extend through the barrier layer 112 to the channel layer 110. The first and second source/drain electrodes 118, 120 are laterally spaced and are electrically coupled to the 2DEG 116. In some embodiments, the first and second source/drain electrodes 118, 120 are ohmically coupled to the 2DEG 116. The first and second source/drain electrodes 118, 120 are conductive may be or comprise, for example, aluminum copper, aluminum, tungsten, copper, doped polysilicon, some other conductive material, or any combination of the foregoing.

In some embodiments, a process for forming the first and second source/drain electrodes 118, 120 comprises patterning the barrier layer 112 to form a pair of electrode openings exposing the channel layer 110. A conductive layer is deposited on the barrier layer 112, filling the electrode openings. Further, the conductive layer is patterned into the first and second source/drain electrodes 118, 120. The patterning of the barrier layer 112 and/or the conductive layer may, for example, be performed by a photolithography/etching process or some other patterning process. The depositing of the conductive layer may, for example, be performed by chemical vapor deposition (CVD), physical vapor deposition (PVD), electroless plating, electroplating, some other deposition process, or any combination of the foregoing.

Also illustrated by the cross-sectional view 1100 of FIG. 11, a gate electrode 122 is formed on the barrier layer, laterally between the first and second source/drain electrodes 118, 120. The gate electrode 122 is conductive and may be or comprise, for example, aluminum copper, aluminum, tungsten, copper, doped polysilicon, some other conductive material, or any combination of the foregoing. In some embodiments, a process for forming the gate electrode 122 comprises depositing a conductive layer and patterning the conductive layer into the gate electrode 122. The patterning may, for example, be performed by a photolithography/etching process or some other patterning process. The depositing of the conductive layer may, for example, be performed by CVD, PVD, electroless plating, electroplating, some other deposition process, or any combination of the foregoing.

During use of the group III-V device, the gate electrode 122 generates an electric field that manipulates the continuity of the 2DEG 116 from the first source/drain electrode 118 to the second source/drain electrode 120. For example, when the gate electrode 122 is biased with a voltage more than a threshold voltage, the gate electrode 122 may generate an electric field depleting an underlying portion of the 2DEG 116 of mobile electrons and breaking the continuity of the 2DEG 116 from the first source/drain electrode 118 to the second source/drain electrode 120 electrode. In some embodiments, the isolation buffer layer 126 act as “back barrier” for the channel layer 110 due to its high resistivity, thereby reducing substrate losses and increasing the soft breakdown voltage of the group III-V device.

While FIG. 11 illustrates formation of the gate electrode 122 according to embodiments in FIG. 1, it is to be appreciated that the gate electrode 122 may alternatively be formed according to embodiments in any one of FIGS. 3A-3C. For example, a group III-V gate layer 302 and the gate electrode 122 may be formed stacked on the barrier layer 112 for embodiments of FIG. 3A. As another example, a gate dielectric layer 304 and the gate electrode 122 may be formed stacked on the barrier layer 112 for embodiments of FIGS. 3B and 3C.

While the substrate 104, the seed buffer layer 102, and the isolation buffer layer 126 are described as being doped with p-type dopants in at least some embodiments of FIGS. 6-11, it is to be appreciated that n-type dopants may alternatively be used for the substrate 104, the seed buffer layer 102, the isolation buffer layer 126, or any combination of the foregoing in other embodiments. While the graded buffer layer 124 is described and illustrated as having three grading buffer layers in at least some embodiments of FIGS. 7-11, it is to be appreciated that the graded buffer layer 124 may have more or less grading buffer layers in other embodiments.

With reference to FIG. 12, a flowchart 1200 of some embodiments of the method of FIGS. 6-11 is provided. The group III-V device formed by the method may, for example, be an enhancement mode HEMT, a depletion mode HEMT, an enhancement mode MISFET, a depletion mode MISFET, or some other group III-V device.

At 1202, a group III-V buffer structure is formed on a substrate. See, for example, FIGS. 6-8. At 1202a, the forming of the group III-V buffer structure comprises epitaxially forming a seed buffer layer on the substrate, where the seed buffer layer is doped. See, for example, FIG. 6. The seed buffer layer may, for example, be doped with p-type dopants. In some embodiments, at 1202b, the forming of the group III-V buffer structure comprises epitaxially forming a graded buffer layer over the seed buffer layer. See, for example, FIG. 7. In some embodiments, at 1202c, the forming of the group III-V buffer structure comprises epitaxially forming an isolation buffer layer on the graded buffer layer. See, for example, FIG. 8.

At 1204, a group III-V heterojunction structure is formed on the group III-V buffer structure. See, for example, FIGS. 9 and 10.

At 1206, a gate electrode and a pair of source/drain electrodes are formed on the group III-V heterojunction structure. See, for example, FIG. 11.

Due to the high doping concentration, the seed buffer layer does not induce formation of a 2DHG in the substrate, along an interface at which the seed buffer layer and the substrate contact. The dopants (e.g., p-type dopants) of the seed buffer layer may, for example, have a positive charge that repels mobile holes in the substrate and prevents the 2DHG from forming. As such, a 2DHG does not reduce a resistivity of the substrate and substrate losses are reduced. Due to the reduced substrate losses, PAE of the group III-V device is enhanced.

While the method described by the flowchart 1200 is illustrated and described herein as a series of acts or events, it will be appreciated that the illustrated ordering of such acts or events are not to be interpreted in a limiting sense. For example, some acts may occur in different orders and/or concurrently with other acts or events apart from those illustrated and/or described herein. Further, not all illustrated acts may be required to implement one or more aspects or embodiments of the description herein, and one or more of the acts depicted herein may be carried out in one or more separate acts and/or phases.

In some embodiments, the present application provides a semiconductor device including: a substrate; a seed buffer layer overlying and directly contacting the substrate, wherein the seed buffer layer includes a group III-V material that is doped and at an interface at which the substrate and the seed buffer layer directly contact; a heterojunction structure overlying the seed buffer layer; a pair of source/drain electrodes overlying the heterojunction structure; and a gate electrode overlying the heterojunction structure, laterally between the source/drain electrodes. In some embodiments, the seed buffer layer includes a group III nitride, wherein the substrate and the seed buffer layer are doped with same doping type. In some embodiments, the seed buffer layer includes aluminum nitride. In some embodiments, the seed buffer layer is p-type. In some embodiments, the seed buffer layer has a doping concentration greater than about 1×10¹⁸ cm⁻³. In some embodiments, the seed buffer layer includes a first seed buffer layer and a second seed buffer layer overlying the first seed buffer layer, wherein the first seed buffer layer has a first ratio of group V atoms to group III atoms, wherein the second seed buffer layer has a second ratio of group V atoms to group III atoms, and wherein the first and second ratios are different. In some embodiments, the substrate has a resistance greater than about 1 kΩ/cm. In some embodiments, the semiconductor device further includes: a graded buffer layer overlying the seed buffer layer; and an isolation buffer layer overlying the graded buffer layer, wherein the isolation buffer layer has a concentration of dopants exceeding about 1×10¹⁸ cm⁻³, and wherein the heterojunction structure overlies the isolation buffer layer.

In some embodiments, the present application provides a method for forming a semiconductor device, the method including: epitaxially forming a seed buffer layer directly on a substrate, wherein the seed buffer layer includes a group III-V material that is doped and at an interface at which the substrate and the seed buffer layer directly contact; epitaxially forming a heterojunction structure overlying the seed buffer layer; forming a pair of source/drain electrodes on the heterojunction structure; and forming a gate electrode on the heterojunction structure, laterally between the source/drain electrodes. In some embodiments, the forming of the seed buffer layer includes growing the seed buffer layer while simultaneously doping the seed buffer layer. In some embodiments, the forming of the seed buffer layer includes: forming a first seed buffer layer on the substrate, wherein the first seed buffer layer is formed at first temperatures, and wherein the first seed buffer layer includes the group III material and is doped; and forming a second seed buffer layer on the first seed buffer layer, wherein the second seed buffer layer is formed at second temperatures greater than the first temperatures, and wherein the second seed buffer layer includes the group III material and is doped. In some embodiments, the first temperatures are less than about 1000° C., wherein the second temperatures are greater than about 1000° C. In some embodiments, the forming of the first seed buffer layer and the forming of the second seed buffer layer are repeated at least once. In some embodiments, the seed buffer layer is doped with p-type dopants including at least one of magnesium, iron, or carbon. In some embodiments, the method further includes: epitaxially forming a graded buffer layer on the seed buffer layer; and epitaxially forming an isolation buffer layer on the graded buffer layer, wherein the isolation buffer layer has a concentration of dopants exceeding about 1×10¹⁸ inverse cubic centimeters (cm⁻³), and wherein the dopants comprise at least one of magnesium, iron, or carbon.

In some embodiments, the present application provides another semiconductor device including: a silicon substrate; a seed buffer layer overlying and directly contacting the silicon substrate, wherein the seed buffer layer includes aluminum nitride that is doped with p-type dopants; a channel layer overlying the seed buffer layer, wherein the channel layer includes a two-dimensional electron gas (2DEG) along a top surface of the channel layer; a barrier layer overlying and contacting the channel layer to define a heterojunction; a pair of source/drain electrodes overlying the channel layer; and a gate electrode overlying the barrier layer, laterally between the source/drain electrodes. In some embodiments, the gate electrode directly contacts the barrier layer. In some embodiments, the method further includes a group III-V gate layer separating the gate electrode from the barrier layer and localized to the gate electrode. In some embodiments, the method further includes a gate dielectric layer separating the gate electrode form the barrier layer. In some embodiments, the gate dielectric layer protrudes through the barrier layer to the channel layer, wherein the gate electrode is sunk into the barrier layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a substrate;
a seed buffer layer overlying and directly contacting the substrate, wherein the seed buffer layer comprises a group III-V material that is doped and at an interface at which the substrate and the seed buffer layer directly contact;
a heterojunction structure overlying the seed buffer layer;
a pair of source/drain electrodes overlying the heterojunction structure; and
a gate electrode overlying the heterojunction structure, laterally between the source/drain electrodes.

2. The semiconductor device according to claim 1, wherein the seed buffer layer comprises a group III nitride, and wherein the substrate and the seed buffer layer are doped with same doping type.

3. The semiconductor device according to claim 1, wherein the seed buffer layer comprises aluminum nitride.

4. The semiconductor device according to claim 1, wherein the seed buffer layer is p-type.

5. The semiconductor device according to claim 1, wherein the seed buffer layer has a doping concentration greater than about 1×10¹⁸ inverse cubic centimeters (cm⁻³).

6. The semiconductor device according to claim 1, wherein the seed buffer layer comprises a first seed buffer layer and a second seed buffer layer overlying the first seed buffer layer, wherein the first seed buffer layer has a first ratio of group V atoms to group III atoms, wherein the second seed buffer layer has a second ratio of group V atoms to group III atoms, and wherein the first and second ratios are different.

7. The semiconductor device according to claim 1, wherein the substrate has a resistance greater than about 1 kilo-ohms/centimeter (kΩ/cm).

8. The semiconductor device according to claim 1, further comprising:
a graded buffer layer overlying the seed buffer layer; and
an isolation buffer layer overlying the graded buffer layer, wherein the isolation buffer layer has a concentration of dopants exceeding about 1×10¹⁸ inverse cubic centimeters (cm⁻³), and wherein the heterojunction structure overlies the isolation buffer layer.

9. A method for forming a semiconductor device, the method comprising:
epitaxially forming a seed buffer layer directly on a substrate, wherein the seed buffer layer comprises a group III-V material that is doped and at an interface at which the substrate and the seed buffer layer directly contact;
epitaxially forming a heterojunction structure overlying the seed buffer layer;
forming a pair of source/drain electrodes on the heterojunction structure; and
forming a gate electrode on the heterojunction structure, laterally between the source/drain electrodes.

10. The method according to claim 9, wherein the forming of the seed buffer layer comprises growing the seed buffer layer while simultaneously doping the seed buffer layer.

11. The method according to claim 9, wherein the forming of the seed buffer layer comprises:
forming a first seed buffer layer on the substrate, wherein the first seed buffer layer is formed at first temperatures, and wherein the first seed buffer layer comprises the group III material and is doped; and
forming a second seed buffer layer on the first seed buffer layer, wherein the second seed buffer layer is formed at second temperatures greater than the first temperatures, and wherein the second seed buffer layer comprises the group III material and is doped.

12. The method according to claim 11, wherein the first temperatures are less than about 1000 degrees Celsius (° C.), and wherein the second temperatures are greater than about 1000° C.

13. The method according to claim 11, wherein the forming of the first seed buffer layer and the forming of the second seed buffer layer are repeated at least once.

14. The method according to claim 9, wherein the seed buffer layer is doped with p-type dopants comprising at least one of magnesium, iron, or carbon.

15. The method according to claim 9, further comprising:
epitaxially forming a graded buffer layer on the seed buffer layer; and
epitaxially forming an isolation buffer layer on the graded buffer layer, wherein the isolation buffer layer has a concentration of dopants exceeding about 1×10¹⁸ inverse cubic centimeters (cm⁻³), and wherein the dopants comprise at least one of magnesium, iron, or carbon.

16. A semiconductor device comprising:
a silicon substrate;
a seed buffer layer overlying and directly contacting the silicon substrate, wherein the seed buffer layer comprises aluminum nitride that is doped with p-type dopants;
a channel layer overlying the seed buffer layer, wherein the channel layer comprises a two-dimensional electron gas (2DEG) along a top surface of the channel layer;
a barrier layer overlying and contacting the channel layer to define a heterojunction;
a pair of source/drain electrodes overlying the channel layer; and
a gate electrode overlying the barrier layer, laterally between the source/drain electrodes.

17. The semiconductor device according to claim 16, wherein the gate electrode directly contacts the barrier layer.

18. The semiconductor device according to claim 16, further comprising:
a group III-V gate layer separating the gate electrode from the barrier layer and localized to the gate electrode.

19. The semiconductor device according to claim 16, further comprising:
a gate dielectric layer separating the gate electrode form the barrier layer.

20. The semiconductor device according to claim 19, wherein the gate dielectric layer protrudes through the barrier layer to the channel layer, and wherein the gate electrode is sunk into the barrier layer.
